(19) United States
(12) Patent Application Publication
(10) Pub. No.: US 2025/0327693 A1
(43) Pub. Date: Oct. 23, 2025

(54) SENSOR ASSEMBLIES

(71) Applicant: Rivian IP Holdings, LLC, Irvine, CA (US)

(72) Inventors: Ryan Lee SHARPLES, Normal, IL (US); Robin Adrian RODRIGUEZ TAUBMANN, Bloomington, IL (US); William Dale MENK, Bloomington, IL (US)

(21) Appl. No.: 18/642,062

(22) Filed: Apr. 22, 2024

(51) Int. Cl. G01D 11/24

(52) U.S. Cl. CPC G01D 11/245

(57) ABSTRACT

Aspects of the present disclosure relate to a sensor assembly. The sensor assembly includes a housing configured to be mounted in a manufacturing environment. The housing includes an interior surface and a channel extending along the interior surface. A sensor is disposed within the housing. The position of the sensor along the channel is adjustable in at least one direction. The sensor is configured to detect an object in the manufacturing environment.

### INTRODUCTION

Sensors are commonly implemented in manufacturing environments to identify objects during various processes. For example, a proximity sensor may be used in a vehicle paint booth to initiate actions, such as painting, when the proximity sensor detects the presence of a vehicle at a predetermined location within the paint booth. Such sensors are typically positioned within a housing to protect the sensor(s) from potential damage, such as exposure to contaminants (e.g., paint) within the manufacturing environment.

### SUMMARY OF THE INVENTION

The present disclosure generally relates to a housing, and more specifically, to a sensor assembly.

In one or more embodiments, a sensor assembly is disclosed. The sensor assembly includes a housing configured to be mounted in a manufacturing environment. The housing includes an interior surface and a channel extending along the interior surface. A sensor is disposed within the housing. The position of the sensor along the channel is adjustable in at least one direction. The sensor is configured to detect an object in the manufacturing environment.

In one or more embodiments, a sensor assembly is disclosed. The sensor assembly includes a housing configured to be mounted in a manufacturing environment. The housing includes an interior surface and a channel formed on the interior surface and extending along a major axis of the housing. The position of a sensor along the channel is adjustable in at least one direction. The sensor is configured to detect an object in the manufacturing environment.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting in scope, and may admit to other equally effective embodiments.

FIG. 1 illustrates an isometric view of an example sensor assembly, according to certain embodiments.

FIG. 2A illustrates an isometric view of the sensor assembly of FIG. 1 in a first position, according to certain embodiments.

FIG. 2B illustrates an isometric view of the sensor assembly of FIG. 1 in a second position, according to certain embodiments.

FIG. 3 illustrates an example modular sensor assembly having a first sensor assembly and a second sensor assembly, according to certain embodiments.

FIG. 4 illustrates an example sensor assembly wedge of FIG. 1, according to certain embodiments.

FIG. 5 illustrates an example coupler of FIG. 1, according to certain embodiments.

### DETAILED DESCRIPTION

It is to be understood that the following disclosure provides many different embodiments, or examples, for implementing different features of various embodiments. Specific examples of components and arrangements are described below to simplify the disclosure. These are, of course, merely examples and are not intended to be limiting. The section headings used herein are for organizational purposes and are not to be construed as limiting the subject matter described.

Sensor assemblies are used in manufacturing environments (e.g., a paint booth) to protect and position sensors such that they may detect objects of interest (e.g., a vehicle) in certain locations within the manufacturing environments without fear that the sensors may become damaged from environmental conditions and/or impacts. Embodiments of the disclosure relate to sensor assemblies that protect a sensor (e.g., a proximity sensor) from damage caused by environmental solvents, paint, and/or impacts from skids and/or personnel within a manufacturing environment. The sensor assembly further enables the position of the sensor within the sensor housing to be adjusted, and enables the sensor housing within the manufacturing environment to be adjusted.

In general, the sensor assembly includes a sensor housing having a channel formed along an interior surface. A sensor is disposed within the sensor housing, and the position of the sensor is adjustable along the channel in one or more directions that are parallel to the interior surface (e.g., lengthwise, along the X-axis). In certain embodiments, a spacer may be coupled to the sensor to adjust the position of the sensor in a direction that is perpendicular to the interior surface (e.g., along the Y-axis). This configuration allows for the sensor to be positioned along the length and height of an interior volume of the sensor housing.

The sensor housing may include one or more connectors on one or more exterior surfaces of the sensor housing. The connector(s) may be operable to couple one or more wedges to the sensor housing via a complementary connector formed on each wedge. The wedge may have a tapered (e.g., triangular) shape extending outward from the housing and having a height that decreases from the connector to the opposite end of the wedge. In certain embodiments, the wedge may have a curved side having a width that narrows from the connector to the opposite end of the wedge. Further, an additional sensor housing may be attached to the sensor housing via a coupler that couples a connector disposed on the sensor housing to a complementary connector disposed on the additional sensor housing. This modularity allows a protective wedge and/or an additional sensor housing to be coupled to either side of the sensor housing in order to form a continuous chain of two or more sensor housings. Alternatively, a first wedge can be coupled to one side of the sensor housing, while a second wedge can be coupled to the opposite side of the sensor housing.

An exterior (e.g., bottom) surface of the sensor housing, the wedge, and/or the coupler may include one or more cavities operable to receive one or more brackets therein. The bracket(s) may be used to mount the sensor assembly within the environment (e.g., to the floor). The brackets are operable to adjust the position of the sensor assembly within the environment. For example, the position may be adjusted along an axis substantially parallel to a length (e.g., the X-axis), a width (e.g., the Z-axis), and/or a height (e.g., the Y-axis) of the sensor housing. In order to access the bracket(s), the connector and/or the wedge may include a housing having a removable panel that provides access to bracket hardware of the bracket(s).

The subject matter provides a robust, modular design for housing a sensor while also enabling a position of the sensor to be adjusted.

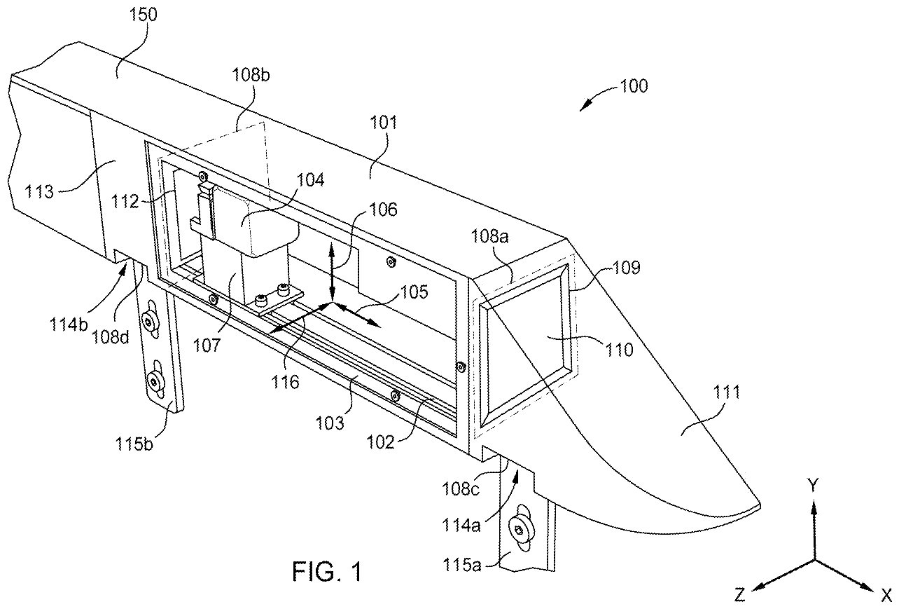

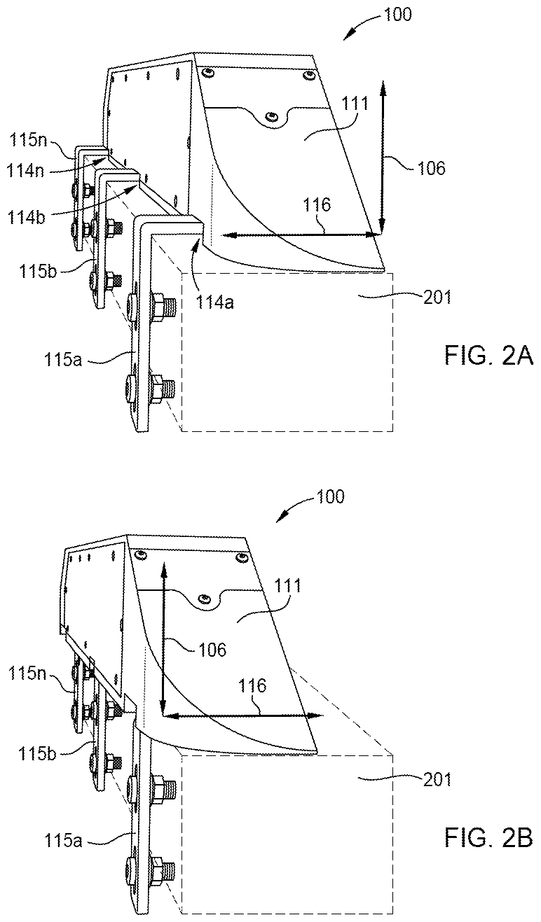

FIG. 1 illustrates an isometric view of an example sensor assembly 100, according to certain embodiments. FIG. 2A illustrates an isometric view of the sensor assembly 100 in a first position, according to certain embodiments. FIG. 2B illustrates an isometric view of the sensor assembly 100 in a second position, according to certain embodiments. FIGS. 1 and 2A-B will be described together for clarity.

As shown in FIG. 1, the sensor assembly 100 includes a housing 101. In certain embodiments, the housing 101 may be configured to be mounted in a manufacturing environment (e.g., a paint booth). The housing 101 has a channel 102 extending along at least one interior surface 103 of the housing 101. A sensor 104 is disposed within the housing 101 (e.g., at a position along the channel 102). The position of the sensor 104 along the channel 102 is adjustable in at least one direction (e.g., the X- and/or Y-axis, as show in FIG. 1). In some embodiments, the sensor 104 may be a proximity sensor. In certain embodiments, the sensor 104 may be configured to detect an object (e.g., a vehicle) in the manufacturing environment.

In some embodiments, the at least one direction may include, without limitation, a first direction 105 along a major axis of the housing (e.g., the X-axis/longitudinal axis), a second direction 106 and/or a third direction 116 along an axis substantially perpendicular to the at least one interior surface 103 (e.g., the Y and/or Z-axis). The sensor assembly 100 includes a spacer 107 disposed between the sensor 104 and the channel 102. The spacer 107 is operable to adjust the position of the sensor 104 in the second direction 106. While FIG. 1 illustrates the use of a spacer 107, in some embodiments, the sensor 104 may be connected directly or indirectly (e.g., via an adapter) to the channel 102.

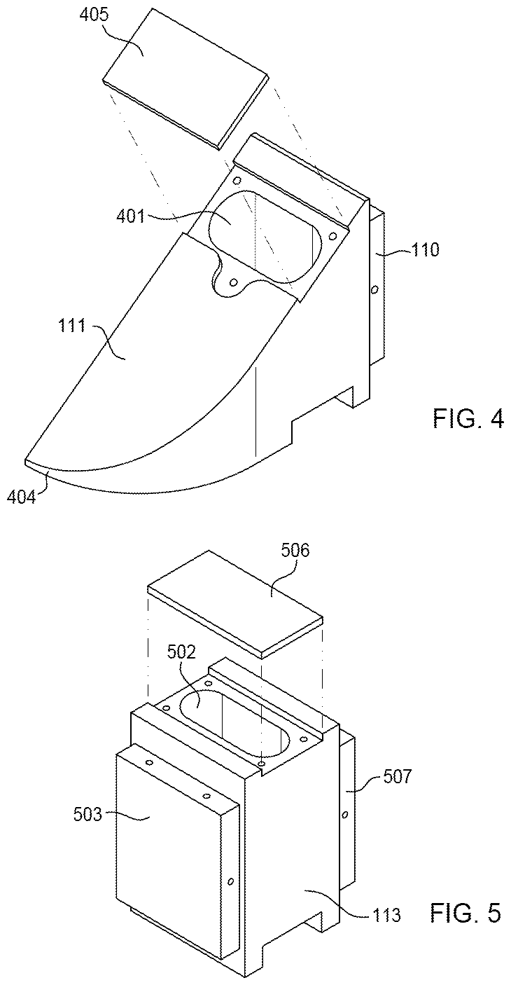

As shown in FIG. 1, the housing 101 of the sensor assembly 100 has a first exterior surface 108a and a second exterior surface 108b opposite the first exterior surface 108a. The first exterior surface 101a includes a first connector 109 configured to couple to at least one of a corresponding connector of an exterior surface of a second sensor assembly 150 or a second connector 110 of a sensor assembly wedge 111. The sensor assembly wedge 111 will be discussed in further detail below with respect to FIG. 4.

The second exterior surface 108b of the sensor assembly 100 includes a third connector 112. In certain embodiments, the third connector 112 may be substantially similar to the first connector 109. As shown in FIG. 1, the first connector 109 disposed on the first exterior surface 108a of the housing 101 is coupled to the second connector 110 of the sensor assembly wedge 111, and the third connector 112 disposed on the second exterior surface 108b is coupled to a coupler 113, which can be connected to the second sensor assembly 150. The second sensor assembly 150 may be substantially similar to the sensor assembly 100. The coupler 113 will be discussed in further detail below with respect to FIG. 5.

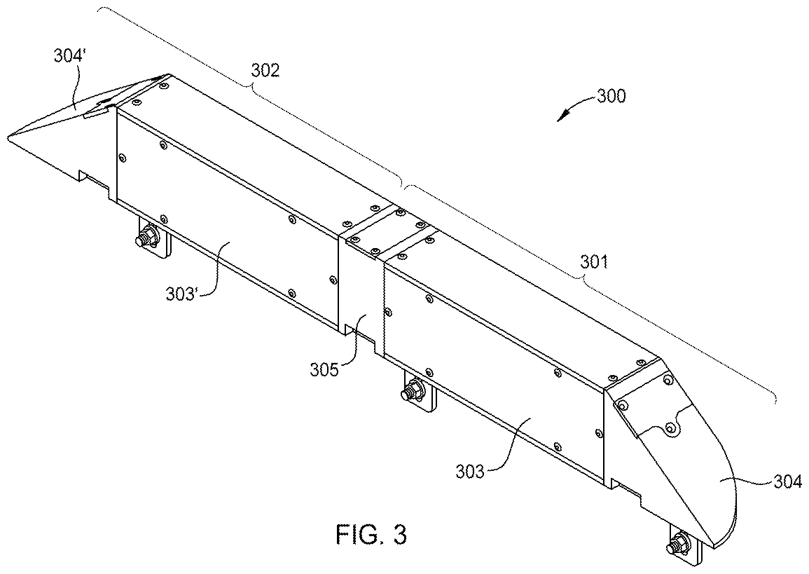

While FIG. 1 illustrates embodiments in which the first exterior surface 108a includes the first connector 109 coupled to the second connector 110 of the sensor assembly wedge 111 and the second exterior surface 108b includes the third connector 112 coupled to the coupler 113, other configurations may be implemented. For example, the second exterior surface 108b may include the first connector 109 coupled to the second connector 110 of the sensor assembly wedge 111, and the first exterior surface 108a may include the third connector 112 coupled to the coupler 113. In some embodiments, a second sensor assembly 150 may connect to the first exterior surface 108a and/or the second exterior surface 108b without a coupler 113. Accordingly, the modularity of these components allows the sensor assembly 100 to be configured for a multitude of different applications, as will be discussed below with respect to FIG. 3.

As illustrated in FIGS. 1 and 2A-B, third exterior surfaces 108c and 108d of the sensor assembly wedge 111 and the coupler 113, respectively, include cavities 114a, 114b . . . 114n (collectively referred to herein as cavities 114) operable to receive brackets 115a, 115b . . . 115n (collectively referred to herein as brackets 115). In some embodiments, brackets 115 may include, without limitation, L-brackets, Z-brackets, U-brackets, offset brackets, and the like. In certain embodiments, illustrated in FIGS. 2A-B, brackets 115 may be mounted to a surface 201 within the manufacturing environment. As the brackets 115 may be received in the cavities 114, the sensor assembly may optionally be flush-mounted to the surface 201.

The brackets 115 are operable to slidably move within the cavity of the housing 101. In some embodiments, the brackets 115 are operable to slidably move in a direction substantially perpendicular to the first direction 105 (e.g., Y- and/or Z-axis). Movement of the brackets 115 provide for movement of the sensor assembly 100 along the second direction 106 and/or a third direction 116 within the manufacturing environment. For example, FIG. 2A illustrates a first position of the sensor assembly 100 relative to the surface 201, and FIG. 2B illustrates a second position of the sensor assembly 100 relative to the surface 201 along the third direction 116 (e.g., Z-axis).

While FIGS. 1 and 2A-B illustrate each cavity 114 including brackets 115, in some embodiments, fewer brackets 115 may be used. For example, the cavity 114a may include the bracket 115a, while the cavity 114b may not include the bracket 115b. Additionally and/or alternatively, in some embodiments, the housing 101, the sensor assembly wedge 111, and/or the coupler 113 may each have fewer or more cavities 114 and/or corresponding brackets 115 than shown in FIGS. 1 and 2A-B.

FIG. 3 illustrates an example modular sensor assembly 300 having a first sensor assembly 301 and a second sensor assembly 302, according to certain embodiments. In certain embodiments, the first sensor assembly 301 may be representative of the sensor assembly 100. In some embodiments, the second sensor assembly may be representative of the second sensor assembly 150. The first sensor assembly 301 includes housing 303 coupled to sensor assembly wedge 304 and coupler 305 on opposing ends of the housing 303. Second sensor assembly 302 includes housing 303′ coupled to the coupler 305 on an opposing end of the housing 500. Sensor assembly wedge 304′ is coupled to the housing 303′ on an opposing end of the coupler 305. The modular sensor assembly 300 may daisy-chain any number of housings, sensor assembly wedges, and/or couplers. The modularity of the sensor assembly 300 allows for sensors to be placed in the manufacturing environment at specific places by adding or removing any number of housings, sensor assembly wedges, and/or couplers, and or adjusting components of the modular sensor assembly 300 as outlined herein.

FIG. 4 illustrates an example sensor assembly wedge 111, according to certain embodiments. As shown in FIG. 4, the sensor assembly wedge 111 includes a tapered shape extending outward relative to the second connector 110. In operation, the tapered shape of the sensor assembly wedge 111 may extend outward relative to the housing 101, as shown in FIGS. 1 and 2A-B. The sensor assembly wedge 111 has a height decreasing from the second connector 110 to an opposing end 404 of the sensor assembly wedge 111.

The sensor assembly wedge 111 has a width that narrows from the second connector 110 to the opposing end 404 of the sensor assembly wedge 111. While FIG. 4 illustrates the sensor assembly wedge 111 having a decreasing height and a narrowing width from the second connector 110 to the opposing end 404, the sensor assembly wedge 111 may be configured to include a decreasing height and a uniform width (e.g., forming a rectangular cross-section when viewed along the Y-axis and a triangular cross-section when viewed along the Z-axis). As shown in FIG. 4, the sensor assembly wedge 111 has a housing 401 configured to connect to a removable panel 405. Housing 401 provides access to one or more fasteners (e.g., screws) disposed within the sensor assembly wedge 111 that enable the bracket 115a to be coupled to a bottom surface of the sensor assembly wedge 111. The removable panel 405 segregates and protects the bracket hardware within the housing 401 from exposure to contaminants (e.g., paint and/or solvents).

FIG. 5 illustrates an example coupler 113, according to certain embodiments. Coupler 113 includes fourth connector 503 and fifth connector 507. Fourth connector 503 and/or fifth connector 507 may each be configured to be coupled to a corresponding connector on the housing 101 (e.g., via third connector 112) and/or the sensor assembly wedge 111 (e.g., via second connector 110). The coupler 113 has a housing 502 configured to connect to a removable panel 506. Housing 502 provides access to bracket hardware (e.g., hardware to bracket 115b) disposed within the coupler 113. The removable panel 506 segregates and protects the bracket hardware within the housing 502 from exposure to contaminants.

Although various embodiments of the present disclosure have been illustrated in the accompanying Drawings and described in the foregoing Detailed Description, it will be understood that the present disclosure is not limited to the embodiments disclosed herein, but is capable of numerous rearrangements, modifications, and substitutions without departing from the spirit of the disclosure as set forth herein.

The term “substantially” is defined as largely but not necessarily wholly what is specified, as understood by a person of ordinary skill in the art. In any disclosed embodiment, the terms “substantially”, “approximately”, “generally”, and “about” may be substituted with “within [a percentage] of” what is specified, where the percentage includes 0.1, 1, 5, and 10 percent.

The foregoing outlines features of several embodiments so that those of ordinary skill in the art may better understand the aspects of the disclosure. Those of ordinary skill in the art should appreciate that they may readily use the disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the disclosure, and that they may make various changes, substitutions, and alterations herein without departing from the spirit and scope of the disclosure. The scope of the invention should be determined only by the language of the claims that follow. The term “comprising” within the claims is intended to mean “including at least” such that the recited listing of elements in a claim are an open group. The terms “a”, “an”, and other singular terms are intended to include the plural forms thereof unless specifically excluded.

Conditional language used herein, such as, among others, “can”, “might”, “may”, “e.g.”, and the like, unless specifically stated otherwise, or otherwise understood within the context as used, is generally intended to convey that certain embodiments include, while other embodiments do not include, certain features, elements, and/or states. Thus, such conditional language is not generally intended to imply that features, elements, and/or states are in any way required for one or more embodiments.

While the above detailed description has shown, described, and pointed out novel features as applied to various embodiments, it will be understood that various omissions, substitutions, and changes in the form and details of the embodiments illustrated can be made without departing from the spirit of the disclosure. As will be recognized, the various embodiments described herein can be embodied within a form that does not provide all of the features and benefits set forth herein, as some features can be used or practiced separately from others. The scope of protection is defined by the appended claims rather than by the foregoing description. All changes which come within the meaning and range of equivalency of the claims are to be embraced within their scope.

What is claimed is:

1. A sensor assembly, comprising:
a housing configured to be mounted in a manufacturing environment, the housing comprising:
an interior surface; and
a channel extending along the interior surface; and
a sensor disposed within the housing, wherein a position of the sensor along the channel is adjustable in at least one direction, the sensor being configured to detect an object in the manufacturing environment.

2. The sensor assembly of claim 1, wherein the at least one direction comprises a first direction along a major axis of the housing.

3. The sensor assembly of claim 1, further comprising a spacer disposed between the sensor and the channel, the spacer operable to adjust the position of the sensor in a second direction.

4. The sensor assembly of claim 1, wherein an exterior surface of the housing comprises a first connector.

5. The sensory assembly of claim 4, wherein the first connector is configured to couple to at least one of a corresponding connector of an exterior surface of a second sensor assembly or a second connector of a sensor assembly wedge.

6. The sensor assembly of claim 5, wherein the first connector is coupled to the second connector of the sensor assembly wedge, the sensor assembly wedge comprising a tapered shape extending outward relative to the housing, wherein a height of the sensor assembly wedge decreases from the second connector to an opposing end of the sensor assembly wedge.

7. The sensor assembly of claim 6, wherein the sensor assembly wedge comprises a width that narrows from the second connector to the opposing end of the sensor assembly wedge.

8. The sensor assembly of claim 6, wherein the sensor assembly wedge comprises a housing including a removable panel that provides access to one or more fasteners disposed within the sensor assembly wedge.

9. The sensor assembly of claim 5, wherein the first connector is coupled to the second sensor assembly via a coupler.

10. The sensory assembly of claim 9, wherein the coupler comprises a housing including a removable panel that provides access to one or more fasteners disposed within the coupler.

11. The sensor assembly of claim 5, wherein:
a second exterior surface of the sensor assembly opposite the exterior surface comprises a third connector;
the exterior surface is coupled to the sensor assembly wedge; and
the third connector of the second exterior surface is coupled to the second sensor assembly via a coupler.

12. The sensor assembly of claim 11, wherein a third exterior surface of at least one of the sensor assembly wedge or the coupler comprises a cavity operable to receive a bracket.

13. The sensor assembly of claim 12, wherein the bracket is operable to slidably move within the cavity of the housing.

14. The sensor assembly of claim 12, wherein the bracket is operable to slidably move in a direction substantially perpendicular to the at least one direction.

15. A sensor assembly, comprising:
a housing configured to be mounted in a manufacturing environment, the housing comprising:
an interior surface; and
a channel formed on the interior surface and extending along a major axis of the housing, wherein a position of a sensor along the channel is adjustable in at least one direction, the sensor being configured to detect an object in the manufacturing environment.

16. The sensor assembly of claim 15, further comprising a spacer operable to adjust the position of the sensor in a second direction.

17. The sensor assembly of claim 16, wherein the second direction comprises a direction along an axis substantially perpendicular to the interior surface.

18. The sensor assembly of claim 15, wherein:
an exterior surface comprises a first connector; and
the first connector is configured to couple to at least one of a corresponding connector of an exterior surface of a second sensor assembly or a second connector of a sensor assembly wedge.

19. The sensor assembly of claim 18, wherein the first connector is coupled to the second connector of the sensor assembly wedge, the sensor assembly wedge comprising a tapered shape extending outward relative to the housing, wherein a height of the sensor assembly wedge decreases from the second connector to an opposing end of the sensor assembly wedge.

20. The sensor assembly of claim 18, wherein the sensor assembly is coupled to the second sensor assembly via a coupler.
